(19) United States
(12) Patent Application Publication
(10) Pub. No.: US 2006/0219865 A1
(43) Pub. Date: Oct. 5, 2006

(54) Apparatus for and method of correcting image in multi-function product

(75) Inventor: Hyun-kyoung Choung, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/377,377

(22) Filed: Mar. 17, 2006

(30) Foreign Application Priority Data
Mar. 18, 2005 (KR) 2005-22533

(51) Int. Cl. H01L 27/00

(52) U.S. Cl. 250/208.1

(57) ABSTRACT

An apparatus for correcting an image includes an image scanning unit, including a light source, that emits a beam generated by the light source toward a document, and scans an image of the document formed by a beam reflected from the document to obtain a scanned image; a beam brightness sensing unit that senses a brightness of the beam generated by the light source; and a correction output unit that corrects the scanned image according to the brightness of the sensed beam sensed by the beam brightness sensing unit to obtain a corrected image, and prints the corrected image.

### CROSS-REFERENCE TO RELATED APPLICATION

This application claims the benefit of Korean Patent Application No. 2005-22533 filed on Mar. 18, 2005, in the Korean Intellectual Property Office, the disclosure of which is incorporated herein by reference in its entirety.

### BACKGROUND OF THE INVENTION

1. Field of the Invention

An aspect of the invention relates to a multi-function product (MFP) such as a scanner including a photocopier or an automatic document feeder (ADF) and a fax, and more particularly to an apparatus for and a method of correcting an image in an MFP.

2. Description of the Related Art

Generally, a multi-function product is an automatic office device that performs multiple functions of office equipment such as a phone, a printer, a photocopier, a scanner, a fax, etc. When scanning a document using such an MFP, a beam generated by a lamp is emitted toward the document and an image of the document is formed by a beam reflected from the document.

FIG. 1 is a graph for explaining an operation of a conventional MFP. The graph illustrates the shading levels of an image printed on a print paper during different periods of time when scanning and printing a document using the MFP. Curve A is the shading level of the image printed during a time when power is first supplied to a lamp, curve B is the shading level of the image printed during a lamp warm-up time, and curve C is the shading level of the image printed after the lamp warm-up time.

As illustrated in the graph, the shading level of curve C corresponds to a normal image printed after a lamp warm up time of 30-40 seconds when the lamp has reached a brightness level of 100%. However, if the image is scanned before the brightness level of the lamp reaches 100%, the shading level of the printed image is lowered as illustrated in curve B, which is lower than curve C showing the shading level of a normal image, thus causing the printed image to be blurred. In addition, it is inconvenient for a user of the MFP to wait during the lamp warm-up time until the brightness level of the lamp reaches 100% in order to print a normal image.

### SUMMARY OF THE INVENTION

An aspect of the invention provides an apparatus for and a method of correcting an image in a multi-function product (MFP) such that a normal image of a document scanned by the MFP can be printed without having to wait during a warm-up time of the MFP by controlling a voltage applied to a laser scanning unit (LSU) according to a brightness of a beam generated by a light source and emitted toward the document for use in scanning the document.

In accordance with an aspect of the invention, there is provided an apparatus for correcting an image, the apparatus including an image scanning unit, including a light source, that emits a beam generated by the light source toward a document, and scans an image of the document formed by a beam reflected from the document to obtain a scanned image; a beam brightness sensing unit that senses a brightness of the beam generated by the light source; and a correction output unit that corrects the scanned image according to the brightness of the beam sensed by the beam brightness sensing unit to obtain a corrected image, and prints the corrected image.

In accordance with an aspect of the invention, the correction output unit may include a printing unit that prints the corrected image; a voltage supply unit that supplies a supply voltage to the printing unit; and a voltage control unit that controls the voltage supply unit so that the supply voltage supplied by the voltage supply unit to the printing unit varies according to the brightness of the beam sensed by the beam brightness sensing unit.

In accordance with an aspect of the invention, the voltage control unit may control the voltage supply unit so that the supply voltage supplied by the voltage supply unit to the printing unit is inversely proportional to the brightness of the beam sensed by the beam brightness sensing unit.

In accordance with an aspect of the invention, the voltage control unit may include a voltage calculator that calculates the supply voltage to be supplied by the voltage supply unit to the printing unit to be effective to correct a shading level of the scanned image to a predetermined reference level according to the brightness of the beam sensed by the beam brightness sensing unit; and a voltage supply controller that controls the voltage supply unit to supply the supply voltage calculated by the voltage calculator to the printing unit.

In accordance with an aspect of the invention, the voltage control unit may include a voltage control table that stores a plurality of supply voltages respectively corresponding to a plurality of brightness levels of the beam sensed by the beam brightness sensing unit; and a voltage supply controller that reads one of the supply voltage corresponding to a current brightness level of the beam sensed by the beam brightness sensing unit from the voltage control table, and controls the voltage supply unit to supply the supply voltage read from the voltage control table to the printing unit.

In accordance with an aspect of the invention, the printing unit may include a beam emitter that emits a beam corresponding to the scanned image at an intensity according to the supply voltage supplied to the printing unit by the voltage supply unit to obtain the corrected image; and an engine that prints the corrected image using the beam emitted from the beam emitter.

In accordance with an aspect of the invention, the beam brightness sensing unit may stop operating if the brightness of the beam sensed by the beam brightness sensing unit has reached a predetermined reference brightness.

in accordance with another aspect of the invention, there is provided a method of correcting an image, the method including emitting a beam generated by a light source toward a document, and scanning an image of the document formed by a beam reflected from the document to obtain a scanned image; sensing a brightness of the beam generated by the light source; and correcting the scanned image according to the brightness of the beam sensed in the sensing of the brightness to obtain a corrected image, and printing the corrected image.

In accordance with an aspect of the invention, the correcting of the scanned image and the printing of the corrected image may include controlling a supply voltage supplied to a printing unit according to the brightness of the beam sensed in the sensing of the brightness; wherein the printing unit controls a shading level of the scanned image according to the supply voltage supplied to the printing unit to obtain the corrected image, and printing the corrected image.

In accordance with an aspect of the invention, the controlling of the supply voltage may include controlling the supply voltage supplied to the printing unit to be inversely proportional to the brightness of the beam sensed in the sensing of the brightness.

In accordance with an aspect of the invention, the controlling of the supply voltage may include calculating the supply voltage to be supplied to the printing unit to be effective to correct the shading level of the scanned image to a predetermined reference level according to the brightness of the beam sensed in the sensing of the brightness; and supplying the supply voltage calculated in the calculating of the supply voltage to the printing unit.

In accordance with an aspect of the invention, the controlling of the supply voltage may include reading one supply voltage corresponding to a current brightness level of the beam sensed in the sensing of the brightness from a voltage control table that stores a plurality of supply voltages respectively corresponding to a plurality of brightness levels of the beam sensed in the sensing of the brightness; and supplying the supply voltage read from the voltage control table to the printing unit.

In accordance with an aspect of the invention, the sensing of the brightness may include determining whether the brightness of the beam sensed in the sensing of the brightness has reached a predetermined reference brightness; and stopping the sensing of the brightness if determined that the brightness of the beam sensed in the sensing of the brightness has reached the predetermined reference brightness.

In accordance with another aspect of the invention, there is provided an apparatus for correcting an image, the apparatus including an image scanning unit, including a light source, that emits a beam generated by the light source toward a document, and scans an image of the document formed by a beam reflected from the document to obtain a scanned image; a beam brightness sensing unit that senses a brightness of the beam generated by the light source; an image correcting unit that corrects a shading level of the scanned image to a predetermined reference level according to the brightness of the beam sensed by the beam brightness sensing unit to obtain a corrected image; and an image storage unit that stores the corrected image.

In accordance with an aspect of the invention, the beam brightness sensing unit may stop operating if the brightness of the beam sensed by the beam brightness sensing unit has reached a predetermined reference brightness.

In accordance with another aspect of the invention, there is provided a method of correcting an image, the method including emitting a beam generated by a light source toward a document, and scanning an image of the document formed by a beam reflected from the document to obtain a scanned image; sensing a brightness of the beam generated by the light source; correcting a shading level of the scanned image according to the brightness of the beam sensed in the sensing of the brightness to obtain a corrected image; and storing the corrected image.

In accordance with an aspect of the invention the sensing of the brightness may include determining whether the brightness of the beam sensed in the sensing of the brightness has reached a predetermined reference brightness; and stopping the sensing of the brightness if the brightness of the beam sensed in the sensing of the brightness has reached the predetermined reference brightness.

In accordance with another aspect of the invention, there is provided an apparatus for correcting an image, the apparatus including an image scanning unit that scans an image of a document to obtain a scanned image in which an image characteristic depends on how long an element of the apparatus has been turned on; and a correction output unit that corrects the scanned image to obtain a corrected image in which the image characteristic does not depend on how long the element of the apparatus has been turned on.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a graph for explaining an operation of a conventional multi-function product (MFP);

FIG. 2 is a block diagram of an apparatus for correcting an image in an MFP according to an embodiment of the invention;

FIG. 3 is a flow chart illustrating a method of correcting an image in an MFP according to another embodiment of the invention;

FIG. 4 is a block diagram of an apparatus for correcting an image in an MFP according to another embodiment of the invention;

FIG. 5 is a flow chart illustrating a method of correcting an image in an MFP according to another embodiment of the invention.

### DETAILED DESCRIPTION OF THE EMBODIMENTS

Reference will now be made in detail to the present embodiments of the invention, examples of which are illustrated in the accompanying drawings, wherein like reference numerals refer to the like elements throughout. The embodiments are described below in order to explain the invention by referring to the figures.

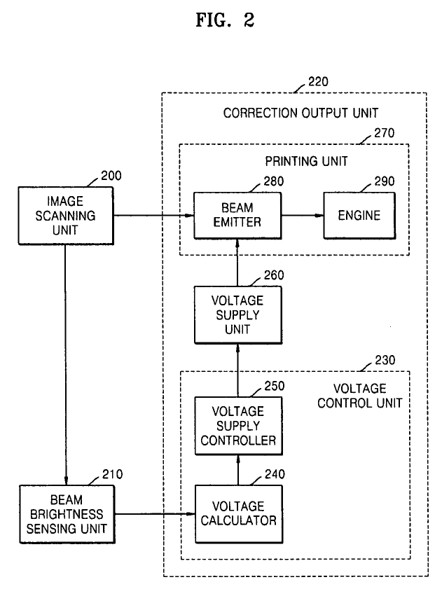

FIG. 2 is a block diagram of an apparatus for correcting an image in an MFP according to an embodiment of the invention. The apparatus includes an image scanning unit 200, a beam brightness sensing unit 210, and a correction output unit 220.

The image scanning unit 200 includes a light source (not shown) such as a lamp, emits a beam generated by the light source toward a document to be scanned, and scans an image of the document formed by a beam reflected from the document.

The beam brightness sensing unit 210 senses the brightness of the beam generated by the light source. The beam brightness sensing unit 210 may sense the brightness of the beam based on an analog image signal output from the image scanning unit 200.

The beam brightness sensing unit 210 stops operating if the brightness of the sensed beam reaches a predetermined reference brightness. This is because the shading level of the image scanned by the image scanning unit 200 does not need to be corrected if the brightness of the beam is equal to or higher than the reference brightness, and thus an unnecessary correction operation can be prevented. Therefore, if the brightness of the sensed beam has reached the predetermined reference brightness, the beam brightness sensing unit 210 does not operate, the scanned image is not corrected, and the scanned image is printed like a scanned image of a document obtained using a conventional MFP.

The correction output unit 220 corrects the scanned image according to the brightness of the beam sensed by the beam brightness sensing unit 210 and prints the corrected image.

The correction output unit 220 includes a voltage control unit 230, a voltage supply unit 260, and a printing unit 270.

The voltage control unit 230 outputs a control signal to the voltage supply unit 260. The control signal depends on the brightness of the beam sensed by the beam brightness sensing unit 210, and is inversely proportional to the brightness of the beam.

The voltage control unit 230 includes a voltage calculator 240 and a voltage supply controller 250.

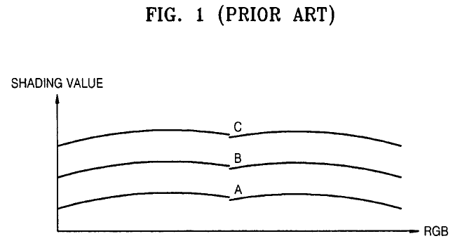

The voltage calculator 240 calculates a supply voltage at which an image is to be printed so that the shading level of the image will be corrected to a predetermined reference level. The supply voltage is inversely proportional to the brightness of the beam sensed by the beam brightness sensing unit 210. The predetermined reference level may be the shading level indicated by curve C illustrated in FIG. 1.

The voltage calculator 240 may be replaced with other elements, such as a voltage control table.

The voltage control table is a table that stores voltages to be supplied to a beam emitter 280 of the printing unit 270 according to the brightness of the beam sensed by the beam brightness sensing unit 210 as illustrated in Table 1. The voltage supply controller 250 outputs a control signal to the voltage supply unit 260 to control the voltage supply unit 260 to supply a supply voltage corresponding to the brightness of the beam sensed by the beam brightness sensing unit 210 to the beam emitter 280 according to the voltage control table illustrated in Table 1.

TABLE 1

| | Brightness of Light Source | Supply Voltage (V) |
|---|---|---|
| A | 33% | 3 |
| B | 66% | 2 |
| C | 100% | 1 |

For example, when the brightness of the beam sensed by the beam brightness sensing unit 210 is 66%, corresponding to the shading level indicated by curve B illustrated in FIG. 1, the voltage supply controller 250 outputs a control signal to the voltage supply unit 260 to control the voltage supply unit 260 to supply 2 volts to the beam emitter 280 according to the voltage control table illustrated in Table 1. If the voltage supply unit 260 supplies 2 volts to the beam emitter 280 in response to the control signal, the printing unit 270 prints the image with the shading level indicated by curve C illustrated in FIG. 1, corresponding to 100% brightness of the beam sensed by the beam brightness sensing unit 210.

If the voltage calculator 240 is used instead of the voltage control table illustrated in Table 1, the voltage supply controller 250 outputs a control signal to the voltage supply unit 260 to control the voltage supply unit 260 to supply the voltage calculated by the voltage calculator 240 to the beam emitter 280.

The voltage supply unit 260 supplies a voltage to the beam emitter 280 according to the control signal output from the voltage supply controller 250.

The printing unit 270 prints the image scanned by the image scanning unit 200 at the shading level corresponding to the voltage supplied to the beam emitter 280 by the voltage supply unit 260.

The printing unit 270 includes the beam emitter 280 and an engine 290.

The beam emitter 280 emits a beam corresponding to an image signal supplied to the beam emitter 280 by the image scanning unit 200. The image signal corresponds to the document scanned by the image scanning unit 200. An intensity of the beam emitted from the beam emitter 280 depends on the voltage supplied to the beam emitter 280 by the voltage supply unit 260. That is, by changing the voltage supplied to the beam emitter 280 using the voltage supply controller 250 according to the brightness of the beam sensed by the beam brightness sensing unit 210, the intensity of the beam emitted from the beam emitter 280 can be changed, thereby making the shading level of an output image produced by the beam emitter 280 the same as the predetermined reference level.

The beam emitter 280 may be a laser scanning unit (LSU) which receives the image signal from the image scanning unit 200 and emits a laser beam toward an organic photoconductor (OPC) drum of the engine 290.

The engine 290 prints the image scanned by the image scanning unit 200 using the beam emitted from the beam emitter 280. The engine 290 prints the scanned image on a print paper by performing charging, exposing, developing, transferring, and fusing and fixing operations. In the charging operation, the surface of the OPC drum is negatively charged. In the exposing operation, the beam emitted from the beam emitter 280 forms an electrostatic latent image on the OPC drum corresponding to the scanned image by neutralizing portions of the charged surface of the OPC drum. In the developing operation, the electrostatic latent image is developed into a visible toner image by toner particles that adhere to the surface of the OPC drum. In the transferring operation, the toner image adhered to the surface of the OPC drum is transferred and adhered to the print paper with static electricity. In the fixing and fusing operation, pressure and heat are applied to the toner image adhered to the print paper so that the toner melts and is fixed and fused to the print paper.

Although the engine 290 has been described as printing the scanned image on a print paper, embodiments of the invention are not limited to this, and the engine 290 may print the scanned image on any printable medium, such as transparencies, cardstock, envelopes, labels, glossy paper, canvas, banner paper, printable CDs and DVDs, etc.

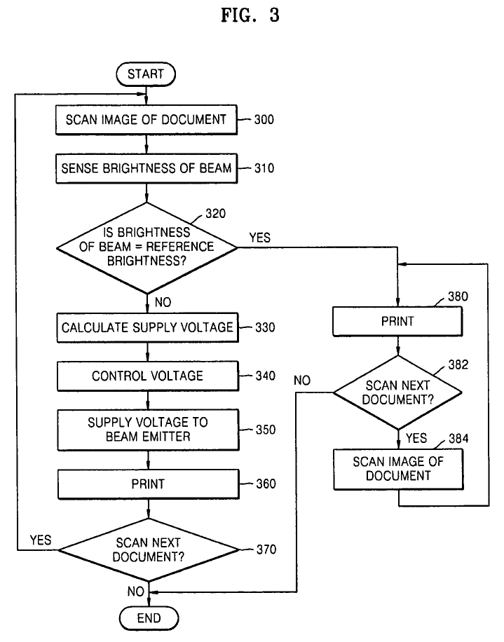

FIG. 3 is a flow chart illustrating a method of correcting an image in an MFP according to an embodiment of the invention.

First, a beam generated by a light source such as a lamp is emitted toward a document, and an image of the document formed by a beam reflected from the document is scanned (operation 300).

Next, the brightness of the beam generated by the light source is sensed (operation 310).

Next, it is determined whether the brightness of the beam sensed in operation 310 has reached a predetermined reference brightness (operation 320).

If it is determined in operation 320 that the brightness of the beam sensed in operation 310 has reached the predetermined reference brightness, the scanned image of the document obtained in operation 300 is printed as it is (operation 380).

Next, it is determined whether there are any more documents to be scanned (operation 382).

If it is determined in operation 382 that there are more documents to be scanned, the beam generated by the light source is emitted toward a next document to be scanned, and an image of the next document formed by a beam reflected from the next document is scanned (operation 384). Next, the scanned image of the next document obtained in operation 384 is printed as it is. That is, the scanned image of the next document is printed without being corrected like in the case of printing a scanned image of a document obtained using a conventional MFP, apart from special situations like when the shading level of the scanned image obtained using the conventional MFP needs to be corrected due to an unstable brightness of a beam generated by a light source.

If it is determined in operation 320 that the brightness of the beam sensed in operation 310 has not reached the predetermined reference brightness, a supply voltage to be supplied to the beam emitter 280 that is effective to correct the shading level to the predetermined reference brightness is calculated according to the brightness of the beam sensed in operation 310 (operation 330). The calculated supply voltage may be inversely proportional to the brightness of the beam sensed in operation 310.

Next, the supply voltage to be supplied to the beam emitter 280 is set to the supply voltage calculated in operation 330 (operation 340).

Operation 330 can be replaced by an operation of searching for the brightness of the beam sensed in operation 310 in the voltage control table illustrated in Table 1 and reading a supply voltage corresponding to the brightness of the sensed beam. The voltage control table stores voltages to be supplied to the printing unit 270 corresponding to the brightness of the sensed beam as illustrated in Table 1. Next, the supply voltage read from the voltage control table in operation 330 is supplied to the printing unit 270 (operation 340).

Next, the supply voltage set in operation 340 is supplied to the beam emitter 280 (operation 350).

The beam emitter 280 controls an intensity of a beam emitted from the beam emitter 280 depending on the voltage supplied to the beam emitter and corrects the shading level of the scanned image of the document obtained in operation 300 to the predetermined reference level, and the engine 290 prints the scanned image at the predetermined reference level (operation 360). In other words, if the voltage supplied to the beam emitter 280 increases, the intensity of the beam emitted from the beam emitter 280 also increases, thereby enabling printing of the scanned image at the predetermined reference level even if the shading level of the scanned image is lower than the predetermined reference level.

After operation 360, it is determined whether there are any more documents to be scanned (operation 370).

If it is determined in operation 370 that there are more documents to be scanned, operations 300 through 370 are repeated.

If it is determined in operation 370 that there are not any more documents to be scanned, a printing operation ends.

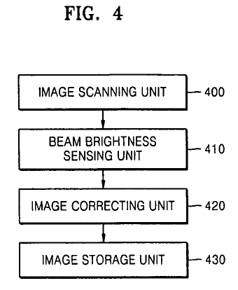

FIG. 4 is a block diagram of an apparatus for correcting an image in an MFP according to another embodiment of the invention. The apparatus includes an image scanning unit 400, a beam brightness sensing unit 410, an image correcting unit 420, and an image storage unit 430.

The image scanning unit 400 includes a light source such as a lamp, and emits a beam generated by the light source toward a document and scans an image of the document formed by a beam reflected from the document.

The beam brightness sensing unit 410 senses the brightness of the beam generated by the light source. The beam brightness sensing unit 410 does not operate if the brightness of the beam has reached a predetermined reference brightness. This is because the shading level of the scanned image obtained by the image scanning unit 400 does not need to be corrected if the brightness of the beam is equal to or higher than the predetermined reference brightness, and thus an unnecessary correction operation can be prevented.

The image correcting unit 420 corrects the shading level of the scanned image obtained by the image scanning unit 400 to the predetermined reference level according to the brightness of the beam sensed by the beam brightness sensing unit 410.

The image storage unit 430 stores therein the corrected image produced by the image correcting unit 420. The image storage unit 430 may be a hard disk drive (HDD) installed in a host computer, an external storage medium such as a floppy disk, a memory card, etc.

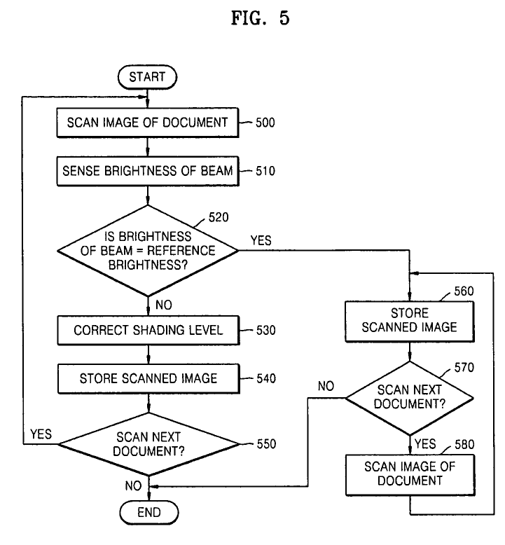

FIG. 5 is a flow chart illustrating a method of correcting an image in an MFP according to another embodiment of the invention.

First, a beam generated by a light source such as a lamp is emitted toward a document, and an image of the document formed by a beam reflected from the document is scanned (operation 500).

Next, the brightness of the beam generated by the light source is sensed (operation 510).

Next, it is determined whether the brightness of the beam sensed in operation 510 has reached a predetermined reference brightness (operation 520). This operation is performed so that an unnecessary correction operation can be prevented since the shading level does not need to be corrected if the brightness of the beam has reached the predetermined reference brightness.

If it is determined in operation 520 that the brightness of the beam has reached the predetermined reference brightness, the scanned image of the document obtained in operation 500 is stored as it is (operation 560).

Next, it is determined whether there are any more documents to be scanned (operation 570).

If it is determined in operation 570 there are more documents to be scanned, the beam generated by the light source is emitted toward a next document to be scanned, and an image of the next document formed by a beam reflected from the next document is scanned (operation 580). Next, the scanned image of the next document obtained in operation 580 is stored as it is (operation 560). That is, the scanned image of the next document is stored without being corrected like in the case of storing a scanned image of a document obtained using a conventional MFP, apart from special situations like when the shading level of the scanned image obtained using the convention MFP needs to be corrected due to an unstable brightness of a beam generated by a light source.

If it is determined in operation 520 that the brightness of the beam has not reached the predetermined reference brightness, the shading level of the scanned image obtained in operation 500 is corrected to a predetermined reference level according to the brightness of the beam sensed in operation 510 (operation 530).

Next, the scanned image as corrected in operation 530 is stored (operation 540).

Next, it is determined whether there are more documents to be scanned (operation 550).

If it is determined in operation 550 that there are more documents to be scanned, the beam generated by the light source is emitted toward the next document and an image of the next document formed by a beam reflected from the document is scanned (operation 500).

If it is determined in operation 550 that there are not any more documents to be scanned, a printing operation ends.

According to an apparatus for and method of correcting an image in an MFP, a user does not have to wait during a warm-up time of the MFP and normal printing can be performed when scanning a document using the MFP by controlling a voltage supplied to an LSU depending on a brightness of a beam emitted toward the document for use in scanning the document.

When printing an image of a scanned document using the MFP, the image of the document is scanned at a normal shading level by controlling a voltage supplied to a beam emitter depending on a brightness of a beam for use in scanning the document without having to wait during the warm-up time of the MFP until the brightness of the beam has reached a brightness level of 100%. Thus, stable printing is achieved without the user having to wait during the warm-up time of the MFP.

Although a few embodiments of the invention have been shown and described, it would be appreciated by those skilled in the art that changes may be made in these embodiments without departing from the principles and spirit of the invention, the scope of which is defined in the claims and their equivalents.

What is claimed is:

1. An apparatus for correcting an image, the apparatus comprising:
an image scanning unit, comprising a light source, that emits a beam generated by the light source toward a document, and scans an image of the document formed by a beam reflected from the document to obtain a scanned image;
a beam brightness sensing unit that senses a brightness of the beam generated by the light source; and
a correction output unit that corrects the scanned image according to the brightness of the beam sensed by the beam brightness sensing unit to obtain a corrected image, and prints the corrected image.

2. The apparatus of claim 1, wherein the correction output unit comprises:
a printing unit that prints the corrected image;
a voltage supply unit that supplies a supply voltage to the printing unit; and
a voltage control unit that controls the voltage supply unit so that the supply voltage supplied by the voltage supply unit to the printing unit varies according to the brightness of the beam sensed by the beam brightness sensing unit.

3. The apparatus of claim 2, wherein the voltage control unit controls the voltage supply unit so that the supply voltage supplied by the voltage supply unit to the printing unit is inversely proportional to the brightness of the beam sensed by the beam brightness sensing unit.

4. The apparatus of claim 2, wherein the voltage control unit comprises:
a voltage calculator that calculates the supply voltage to be supplied by the voltage supply unit to the printing unit to be effective to correct a shading level of the scanned image to a predetermined reference level according to the brightness of the beam sensed by the beam brightness sensing unit; and
a voltage supply controller that controls the voltage supply unit to supply the supply voltage calculated by the voltage calculator to the printing unit.

5. The apparatus of claim 2, wherein the voltage control unit comprises:
a voltage control table that stores a plurality of supply voltages respectively corresponding to a plurality of brightness levels of the beam sensed by the beam brightness sensing unit; and
a voltage supply controller that reads one of the supply voltages corresponding to a current brightness level of the beam sensed by the beam brightness sensing unit from the voltage control table, and controls the voltage supply unit to supply the supply voltage read from the voltage control table to the printing unit.

6. The apparatus of claim 2, wherein the printing unit comprises:
a beam emitter that emits a beam corresponding to the scanned image at an intensity according to the supply voltage supplied to the printing unit by the voltage supply unit to obtain the corrected image; and
an engine that prints the corrected image using the beam emitted from the beam emitter.

7. The apparatus of claim 1, wherein the beam brightness sensing unit stops operating if the brightness of the beam sensed by the beam brightness sensing unit has reached a predetermined reference brightness.

8. A method of correcting an image, comprising:
emitting a beam generated by a light source toward a document, and scanning an image of the document formed by a beam reflected from the document to obtain a scanned image;
sensing a brightness of the beam generated by the light source; and
correcting the scanned image according to the brightness of the beam sensed in the sensing of the brightness to obtain a corrected image, and printing the corrected image.

9. The method of claim 8, wherein the correcting of the scanned image and the printing of the corrected image comprises controlling a supply voltage supplied to a printing unit according to the brightness of the beam sensed in the sensing of the brightness;
wherein the printing unit controls a shading level of the scanned image according to the supply voltage supplied to the printing unit to obtain the corrected image, and prints the corrected image.

10. The method of claim 9, wherein the controlling of the supply voltage comprises controlling the supply voltage supplied to the printing unit to be inversely proportional to the brightness of the beam sensed in the sensing of the brightness.

11. The method of claim 9, wherein the controlling of the supply voltage comprises:
calculating the supply voltage to be supplied to the printing unit to be effective to correct the shading level of the scanned image to a predetermined reference level according to the brightness of the beam sensed in the sensing of the brightness; and
supplying the supply voltage calculated in the calculating of the supply voltage to the printing unit.

12. The method of claim 9, wherein the controlling of the supply voltage comprises:
reading one supply voltage corresponding to a current brightness level of the beam sensed in the sensing of the brightness from a voltage control table that stores a plurality of supply voltages respectively corresponding to a plurality of brightness levels of the beam sensed in the sensing of the brightness; and
supplying the supply voltage read from the voltage control table to the printing unit.

13. The method of claim 8, wherein the sensing of the brightness comprises:
determining whether the brightness of the beam sensed in the sensing of the brightness has reached a predetermined reference brightness; and
stopping the sensing of the brightness if determined that the brightness of the beam sensed in the sensing of the brightness has reached the predetermined reference brightness.

14. An apparatus for correcting an image, the apparatus comprising:
an image scanning, unit comprising a light source, that emits a beam generated by the light source toward a document, and scans an image of the document formed by a beam reflected from the document to obtain a scanned image;
a beam brightness sensing unit that senses a brightness of the beam generated by the light source;
an image correcting unit that corrects a shading level of the scanned image to a predetermined reference level according to the brightness of the beam sensed by the beam brightness sensing unit to obtain a corrected image; and
an image storage unit that stores the corrected image.

15. The apparatus of claim 14, wherein the beam brightness sensing unit stops operating if the brightness of the beam sensed by the beam brightness sensing unit has reached a predetermined reference brightness.

16. A method of correcting an image, the method comprising:
emitting a beam generated by a light source toward a document, and scanning an image of the document formed by a beam reflected from the document to obtain a scanned image;
sensing a brightness of the beam generated by the light source;
correcting a shading level of the scanned image according to the brightness of the beam sensed in the sensing of the brightness to obtain a corrected image; and
storing the corrected image.

17. The method of claim 16, wherein the sensing of the brightness comprises:
determining whether the brightness of the beam sensed in the sensing of the brightness has reached a predetermined reference brightness; and
stopping the sensing of the brightness if the brightness of the beam sensed in the sensing of the brightness has reached the predetermined reference brightness.

18. An apparatus for correcting an image, the apparatus comprising:
an image scanning unit that scans an image of a document to obtain a scanned image in which an image characteristic depends on how long an element of the apparatus has been turned on; and
a correction output unit that corrects the scanned image to obtain a corrected image in which the image characteristic does not depend on how long the element of the apparatus has been turned on.

19. The apparatus of claim 18, wherein the image characteristic is a shading level.

20. The apparatus of claim 18, wherein the image characteristic of the corrected image is equal to the image characteristic of a scanned image obtained by the image scanning unit after the element of the apparatus has been turned on for at least a warm-up time of the element of the apparatus regardless of how long the element of the apparatus has actually been turned on.
